(19) United States
(12) Patent Application Publication
(10) Pub. No.: US 2022/0336342 A1
(43) Pub. Date: Oct. 20, 2022

(54) Wiring Trace Morphology Structure for High Speed Applications

(71) Applicant: Apple Inc., Cupertino, CA (US)

(72) Inventors: Zheng Zhou, Tempe, AZ (US); Jun Chung Hsu, Cupertino, CA (US)

(21) Appl. No.: 17/230,774

(22) Filed: Apr. 14, 2021

(51) Int. Cl. H01L 23/528; H01Q 1/22; H01L 23/66

(52) U.S. Cl. CPC H01L 23/528; H01Q 1/2283; H01L 23/66

(57) ABSTRACT

Routing substrates, methods of manufacture, and electronic assemblies including routing substrates are described. In an embodiment, a routing substrate includes a metal routing layer including a first set of first wiring traces and a second set of second wiring traces, where first top surfaces of the first wiring traces are characterized by a lower RMS surface roughness (Rq) than the second top surfaces of the second wiring traces.

### BACKGROUND

### Field

Embodiments described herein relate to routing substrates, and more particularly to electrical traces.

### Background Information

Routing substrates for application in semiconductor packaging and connection between electronic components can assume a variety of configurations depending upon application. Common routing substrates include rigid circuit boards, flexible circuit boards and flexible cables (collectively referred to as flex circuits), and rigid-flex circuits including both rigid and flexible substrates laminated together, print circuit boards (PCBs), interposers, and high-density redistribution layers (RDLs).

Current wireless assemblies may commonly include a routing substrate to connect multiple radio frequency (RF) components such as transceivers, receivers, antennae, voltage sources, amplifiers, RF switches, etc. For example, routing substrates may be included within component packages (e.g. as package substrates), as well as to connect separate components (e.g. as flex cable, or circuit board). As wireless frequencies continue to increase, the current trend is to reduce distance between the antenna and RF component to reduce loss and improve electrical performance. For example, this may be achieved with antenna-in-package assemblies where the antenna is integrated with an RF chip in an integrated circuit (IC) package, or antenna-on-board assemblies where the antenna and RF chip are mounted on the same circuit board.

### SUMMARY

Routing substrates, methods of manufacture, and electronic assemblies including routing substrates are described. In an embodiment, a routing substrate includes a metal routing layer including a first set of first wiring traces and a second set of second wiring traces, where first top surfaces of the first wiring traces are characterized by a lower RMS surface roughness (Rq) than the second top surfaces of the second wiring traces. When integrated into an electronic assembly, the first wiring traces may connect a first component with a second component. For example, the first wiring traces may be utilized to provide high speed/frequency applications with a reduced insertion loss, and the second traces with higher Rq provide requisite adhesion to an overlying insulator layer (e.g. low loss dielectric) to preserve or enhance the adhesion between metal and dielectric material to prevent a delamination induced reliability problem.

### BRIEF DESCRIPTION OF THE DRAWINGS

FIG. 1 is a schematic cross-sectional side view illustration of a routing substrate including select wiring traces with lower roughness in accordance with embodiments.

FIG. 2 is a schematic cross-sectional side view illustration of an electronic assembly including a plurality of components mounted on a routing substrate including select wiring traces with lower roughness in accordance with embodiments.

FIG. 3 is a schematic cross-sectional side view illustration of an electronic assembly including a plurality of components coupled with a routing substrate including select wiring traces with lower roughness in accordance with embodiments.

FIG. 4A is a schematic cross-sectional side view illustration of as-grown wiring traces prior to a post growth roughening operation in accordance with an embodiment.

FIG. 4B is a schematic cross-sectional side view illustration of roughening a select wiring trace in accordance with an embodiment.

FIG. 4C is a schematic cross-sectional side view illustration of select side surface roughening of wiring traces in accordance with an embodiment.

FIG. 5 is a schematic cross-sectional side view illustration of a wiring trace with graded grain size growth in accordance with an embodiment.

FIG. 6 is a schematic cross-sectional side view illustration of wiring traces grown with graded grain size growth in accordance with an embodiment.

FIG. 7 is a schematic cross-sectional side view illustration of select wiring traces grown with different grain sizes in accordance with an embodiment.

FIG. 8 is a schematic cross-sectional side view illustration of a select wiring trace including an additional top skin layer with larger grain size in accordance with an embodiment.

FIGS. 9A-9B are schematic cross-sectional side view illustrations of using local laser modulation to control local surface roughness and grain size in accordance with an embodiment.

FIGS. 10A-10H are schematic cross-sectional side view illustrations for a sequence of forming select wiring traces with smooth top surfaces in accordance with an embodiment including masking during roughening.

FIGS. 11A-11I are schematic cross-sectional side view illustrations for a sequence of forming select wiring traces with smooth top surfaces in accordance with an embodiment including selective growth and masking during roughening.

FIGS. 12A-12H are schematic cross-sectional side view illustrations for a sequence of forming wiring traces with roughened side surfaces and smooth top surfaces in accordance with an embodiment.

FIG. 13 is a chart illustrating modeling data for peel strength of an overlying insulation layer as a variation of underlying wiring layer roughness in accordance with embodiments.

FIG. 14 includes images of ten-layer test routing substrates with different wiring trace top surface roughness before and after thermal cycling in accordance with embodiments.

FIG. 15 is a chart illustrating 10 mm transmission line modeling data for insertion loss as a variation of frequency for wiring traces of different RMS surface roughness on bottom, top, and side surfaces in accordance with embodiments.

### DETAILED DESCRIPTION

Embodiments describe routing substrates, electronic assemblies including routing substrates, and methods of manufacture thereof. In an embodiment, a routing substrate includes a plurality of metal routing layers and insulation layers in which a first metal routing layer of the plurality of metal routing layers includes a first set of wiring traces and a second set of wiring traces, with first top surfaces of the first wiring traces characterized by a lower root mean square (RMS) surface roughness (Rq) than second top surfaces of the second wiring traces.

In one aspect, embodiments describe routing substrate structures with reduced roughness on select wiring traces (e.g. lines or planes), while having higher roughness on other wiring trace (line or plane) area. In particular, the select wiring traces with lower RMS surface roughness may be utilized for high speed/frequency applications, such as, but not limited to, mmWave communication, serializer/deserializer (SerDes), peripheral component interconnect (PCI), etc. For example, it has been observed that insertion loss can be significantly reduced with copper wiring trace roughness reduction when used for high frequency applications, such as at 24 GHz range and above. Even more particularly, it has been observed that at the Frequency Ranges 2 (FR2) from 24.35 GHz to 52.6 GHz, a majority of alternating electric current may move to the surfaces of wiring traces. For example, it has been observed that high frequency currents may flow in the outermost two microns of the wiring traces. In accordance with embodiments, this may depend upon surface roughness of the wiring traces, as well as skin depth/thickness. In an embodiment, select wiring traces roughness are designed with reduced RMS surface roughness (Rq) on top, side, and even bottom surfaces to reduce insertion loss.

In the following description, wiring trace morphology is characterized by an RMS surface roughness. In interest of conciseness, RMS surface roughness, or Ra, may also be more generally referred to as surface roughness, roughness, or comparatively as being smoother or rougher, or having a higher or lower value. In each instance, usage of the more generic terms may more specifically refer to RMS surface roughness.

In another aspect, embodiments describe routing substrate structures designed the limit delamination. In accordance with embodiments, the routing substrate may combine insulation layers formed of low loss dielectric materials with copper wiring traces. It has been observed that low loss dielectric materials, with a dissipation factor (Df) less than 0.007, may not have as good adhesion to copper wiring traces as high loss dielectric materials. As a result, low loss dielectric materials may inherently be prone to poor adherence to metal surface, causing failure in the routing substrate. This trend may be for both low dielectric constant (low-k) and high dielectric constant (high-k) materials. In accordance with embodiments, only select wiring traces are designed with low surface roughness, with the remainder of the wiring traces in the routing substrate designed with higher surface roughness. Such a hybrid approach to wiring trace roughness may enable integration of low loss dielectric materials while also reducing insertion loss.

The hybrid roughness configurations in accordance with embodiments can be accomplished using a variety of processing techniques.

In some embodiments, a smoother surface can be achieved using a mask layer while a metal routing layer is roughened in a post-growth operation. For example, such a mask layer can be formed by plating excess material on select traces, and then be selectively removed the excess material after roughening. In an embodiment, excess nickel can be plated on top of copper traces, and be selectively removed after roughening.

In some embodiments, a smoother surface can be achieved by selectively plating a smoother layer on select traces. For example, this may be achieved using a modified electrolytic plating chemistry and/or applying a higher plating current. As a result, the select traces may be thicker than the comparatively rougher traces. The added thickness on the select traces may also be characterized by a larger average grain size.

A larger grain size can also be accomplished using alternative techniques such as laser light to locally heat up trace surfaces and form a skin with increased grain size. In an embodiment, local laser modulation can be performed after roughing the metal routing layer. The laser can also locally modulate the underlying/adjacent dielectric layer for promoting adhesion with the next dielectric layer.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “over”, “to”, “between”, and “on” as used herein may refer to a relative position of one layer with respect to other layers. One layer “over”, or “on” another layer or mounted “on” or in “contact” with another layer may be directly in contact with the other layer or may have one or more intervening layers. One layer “between” layers may be directly in contact with the layers or may have one or more intervening layers.

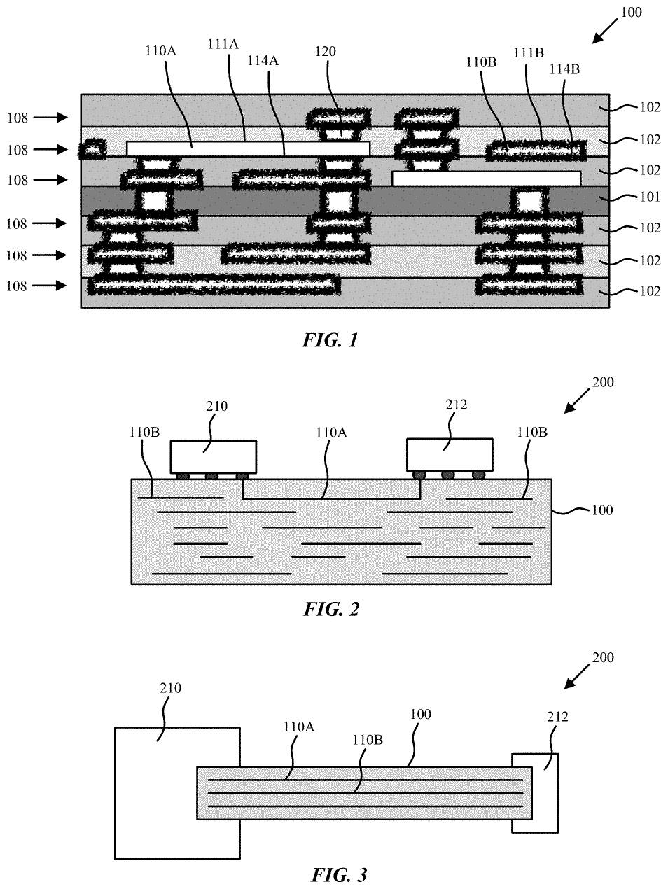

Referring now to FIG. 1 a cross-sectional side view illustration is provided of a routing substrate 100 including select wiring traces with lower roughness in accordance with embodiments. The routing substrates 100 in accordance with the various embodiments described herein may assume various configurations such as redistribution layers or printed circuit boards (PCBs), each including one or more metal routing layers 108 and insulation (e.g. dielectric) layers 102. Furthermore, the routing substrates 100 may be rigid or flexible, and in an embodiment may include a rigid-flex connection.

The routing substrates 100 may be formed of a variety of materials, including traditional substrates such as FR-2 (a phenolic paper impregnated with resin), FR-4 (a woven fiberglass impregnate with resin), RCC (resin coated copper), ABF (Ajinomoto Build-up Film) metal or metal core substrates, silicon core substrates, ceramics, polymers, etc. Metal routing layers 108 and vias 120 may be formed of suitable materials, such as copper, gold, aluminum, etc. Routing substrates may be coreless substrates, or include cores 101. In accordance with embodiments, the core 101 may be a laminate body. For example, the core 101 can be a composite of woven fiberglass cloth and polymer (e.g. resin). The core 101 may be formed of a variety of suitable PCB materials including FR4, prepreg, polyimide, etc. The core 101 may be rigid or flexible. Vertical vias 120 may be filled copper, for example, formed using a plating technique after drilling via holes through the core 101.

Routing substrates 100 can also be formed using thin film techniques. For example, the insulation layer(s) 102 may be formed of a photoimageable dielectric material including polymers (e.g. polyimide, epoxy, epoxy blends, etc.) or inorganic materials (e.g. oxide, nitride), while the metal routing layers 108 and vias 120 may be formed of a suitable metal, including copper.

As shown in FIG. 1, in an embodiment, the routing substrate 100 includes a plurality of metal routing layers 108 and insulation layers 102. A first metal routing layer 108 of the plurality of metal routing layers includes a first set of one or more first wiring traces 110A and a second set of one or more second wiring traces 110B, where first top surfaces 111A of the first wiring traces 110A are characterized by a lower RMS surface roughness (Rq) than second top surfaces 111B of the second wiring traces 110B.

In accordance with embodiments, the lower Rq can reduce insertion loss, particularly when the wiring traces are used for high speed/frequency applications. Thus, the lower Rq can be reserved for select wiring traces, while the surrounding wiring traces within the same metal routing layer 108 can have higher Rq to facilitate adhesion to the insulation layers 102 and reduce potential for delamination. In an embodiment, an insulation layer 102 including a low loss material with a dielectric Df less than 0.007 is formed over the metal routing layer 108 including a first set of first wiring traces 110A and a second set of second wiring traces 110B.

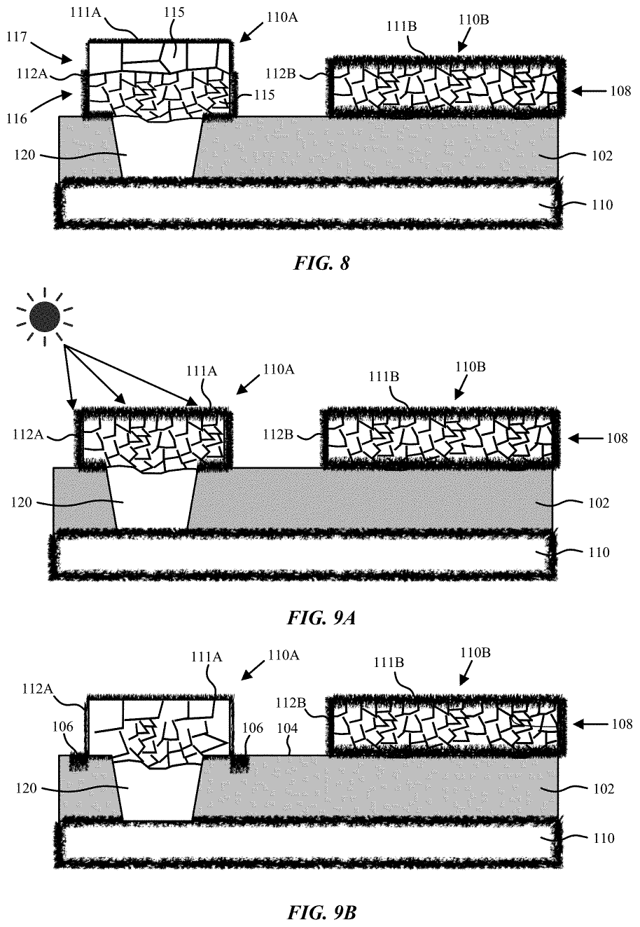

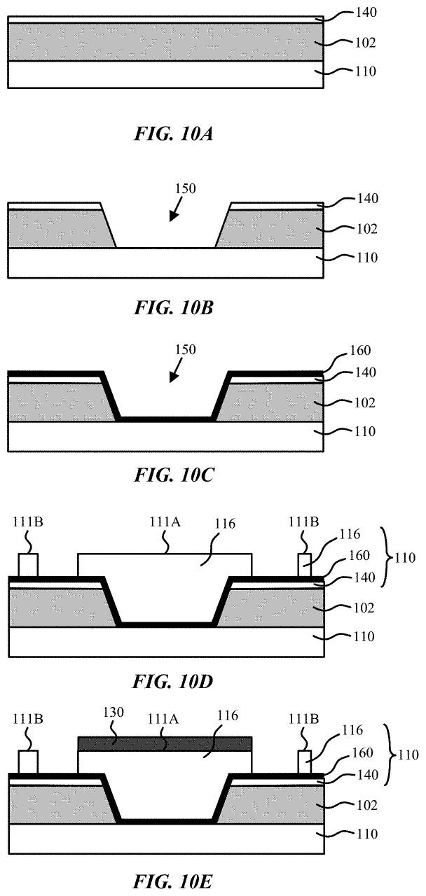

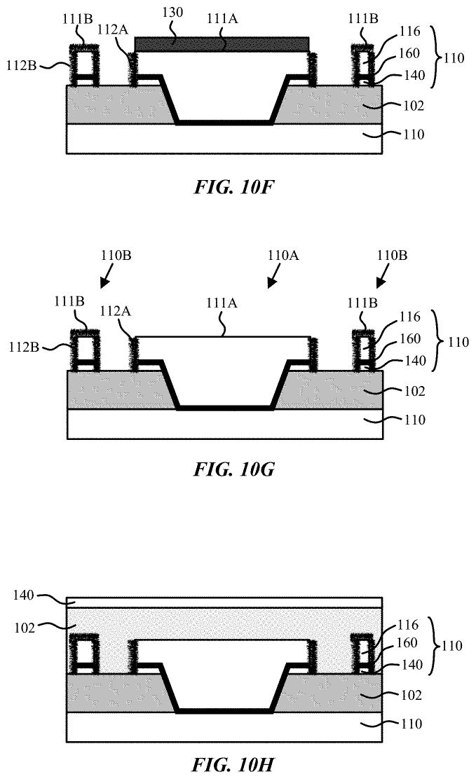

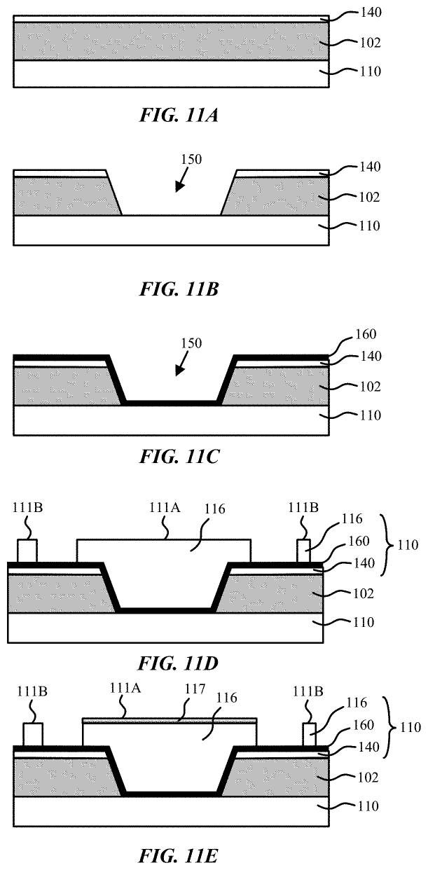

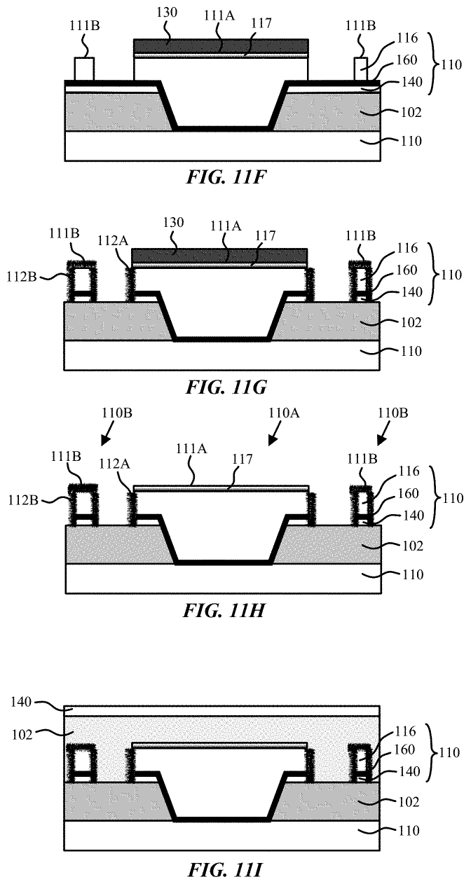

As an example, in some embodiments the first top surfaces 111A are characterized by an RMS surface roughness (Rq) that is at least 0.10 μm less than that for the second top surfaces 111B. The difference could be even greater such as at least 0.15 μm, or 0.20 μm, or more. For example, the second top surfaces 111B may have an RMS surface roughness (Rq) of greater than 200 nm, or more particularly greater than 300 nm, such as 400 nm or more, while the first top surfaces 111A may have an Rq of 200 nm or less (e.g. optimized smooth electrolytic plated top surface as will be describe in more detail with regard to FIG. 10D) such as 150 nm, 100 nm or even 50 nm (e.g. ultra-smooth skin layer, as will be described in more detail with regard to FIGS. 8, 11E). In addition, in some embodiments, volume ratios of the first wiring traces 110A and second wiring traces 110B are designed with a larger volume ratio or number of the second wiring traces 110B within a metal routing layer 108 to provide sufficient adhesion to accommodate the comparatively lower roughness first wiring traces 110A.

It is to be appreciated, that while attention is drawn to roughness of the top surfaces of the wiring traces, that side surfaces and bottom surfaces also affect insertion losses. Thus, surface morphology, including grain size and Rq can be controlled on the bottom surfaces and side surfaces. In some embodiments, the bottom surfaces 114B of the second wiring traces 110B are smoother (lower Rq) than the top surfaces 111B of the second wiring traces 110B. For example, this may be attributed to a roughening operation performed after growth of the wiring traces. Similarly, the bottom surfaces 114A of the first wiring traces 110A can be smoother (lower Rq) than the top surfaces 111B of the second wiring traces 110B.

Referring now to FIGS. 2-3 two exemplary illustrations are provided of electronic assemblies 200 including routing substrates 100 described herein. In the exemplary embodiment illustrated in FIG. 2, components 210, 212 are mounted on the routing substrate 100. For example, the routing substrate 100 may be a rigid or flexible PCB. In the embodiment illustrated in FIG. 3, the components 210, 212 are coupled to a flexible routing substrate 100, such as a flexible cable or rigid-flex circuit. In each embodiment, the routing substrates include first wiring traces 110A with lower roughness that electrically connect the first components 210 with the second components 212. In an exemplary wireless module implementation, the first components 210 can include a radio frequency integrated circuit (RFIC) die, and the second components 212 include an antenna. In another configuration, the first and second components 210, 212 include a central processing unit (CPU) and/or graphics processing unit (GPU). Alternatively, the routing substrates 100 can connect a memory component to another component, etc.

In some embodiments, the first top surfaces 111A of the first wiring traces 110A have a larger average grain size than the second top surfaces 111B of the second wiring traces 110B. For example, this may be accomplished with selective growth or thermal (e.g. laser) treatment. The first wiring traces 110A may also be thicker than the second wiring traces 110B. For example, a skin layer with larger average grain size may be selectively grown on a bulk layer of the first wiring traces 110A to achieve lower Rq. Differences in thickness can also be due to loss of volume during physical or chemical roughening of the second wiring traces 110B. In such an instance, average grain size for the first top surfaces 111A and second top surfaces 111B may be approximately the same. Physical roughing, such as sand blasting or sputtering can be accompanied by an increase in dislocation density at the treated surface. Chemical roughening, such as wet or dry etching may be accompanied by widening and deepening of trenches along grain boundaries. For example, for copper-based wiring traces a wet etch chemical roughening process can be performed with a hydrogen peroxide based chemistry.

Processing to reduce roughness can also be performed along the side surfaces of select wiring traces or all wiring traces. For example, selective growth or laser treatment can be used to increase grain size along the side surfaces of the wiring traces. Where laser treatment is used, the top surface of the underlying insulation layer can also be roughened adjacent the treated wiring traces. Thus, the top surface of the insulation layer can include a bulk area characterized by a bulk surface roughness (Rq) and an altered surface area adjacent the treated select wiring traces, where the altered surface area is characterized by a higher surface roughness (Rq) than the bulk surface roughness (Rq).

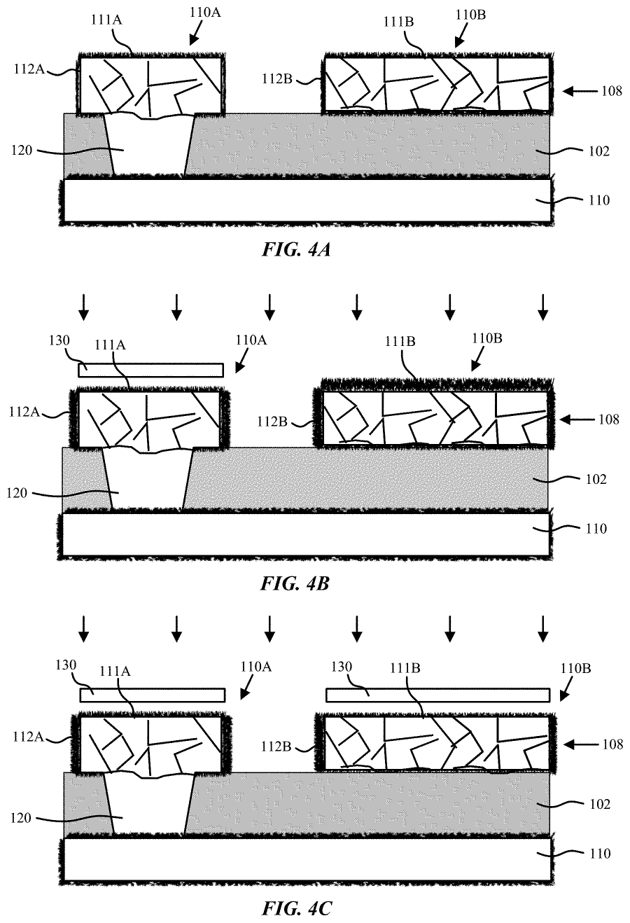

Referring now to FIGS. 4A-9B schematic cross-sectional side view illustrations are provided for a variety of methods or conditions of controlling roughness of the top surfaces and side surfaces of wiring traces in accordance with embodiments. It is to be appreciated that while various methods or conditions are described and illustrated separately, that many of the methods and conditions can be combined. Thus, separate illustration is not intended to exclude combinations thereof.

FIGS. 4A-4B are schematic cross-sectional side view illustrations of as-grown wiring traces before and after a selective roughening operation in accordance with an embodiment. Specifically, FIGS. 4A-4B illustrate the use of a mask layer 130 over the first wiring traces 110A during post growth roughening second wiring traces 110B. As previously described, roughening can be any of physical or chemical roughening techniques, which may focus on the top surfaces and/or side surfaces of the wiring traces. The mask layers 130 in accordance with embodiments can be applied in a variety of manners, such as a patterned plate that can be provided over the routing substrate 100 during processing, or as a deposited layer. For example, the mask layer 130 can be a deposited dielectric or metallic layer that is selectively removed after roughening, or a layer that is fully consumed during roughening. In some embodiments, the mask layer 130 is a metal layer, such as nickel, that can be formed during formation of metal routing layers 108, and selectively removed by etching (e.g. selective etching from copper bulk layer). Upon removal, the resultant first top surfaces 111A of first wiring traces 110A are smoother, with lower Rq, than the second top surfaces 111B of the second wiring traces 110B. The first side surfaces 112A however may have similar roughness as the second side surfaces 112B if not covered with the mask layer 130.

Referring now to FIG. 4C a variation of FIG. 4B is shown, where instead a mask layer 130 is provided over both sets of wiring traces 110A, 110B within a metal routing layer 108. In such an embodiment, the side surfaces 112A, 112B are selectively roughened, while the top surfaces 111A, 111B are smoother. In this manner, the roughened side surfaces 112A, 112B may provide adhesion for the overlying insulation layer to be formed, while providing smooth top surfaces for all wiring traces.

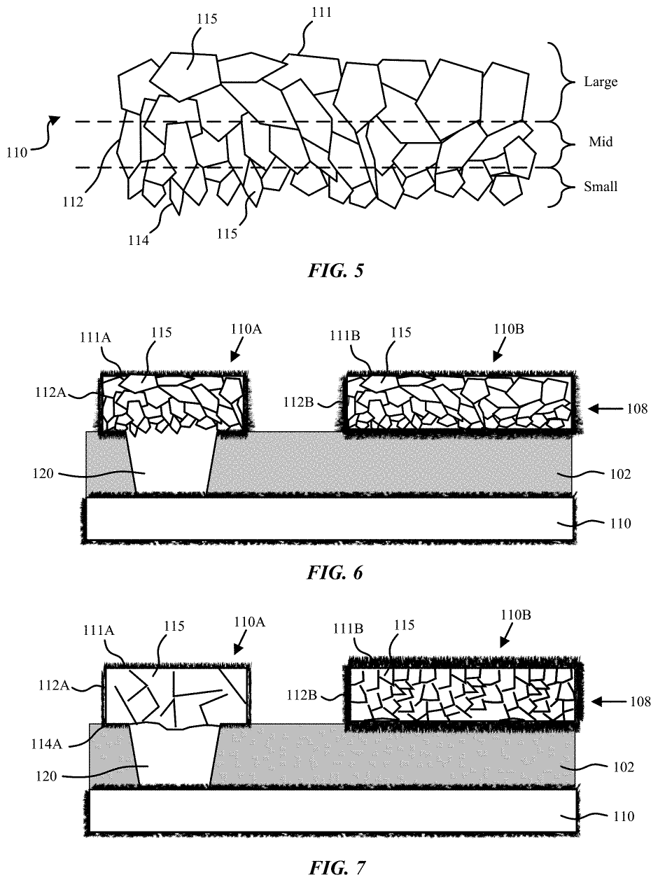

FIG. 5 is a schematic cross-sectional side view illustration of a wiring trace 110 with graded grain size growth in accordance with an embodiment. As shown, the wiring trace 110 includes smaller grains 115, or crystals, at the bottom surface 114 and larger grains 115 at the top surface 111 of the wiring trace. Modulation of grain 115 size can be achieved by altering the plating chemistry and applying higher plating current to retard the metal, such as copper (Cu), crystal initiation point and induce larger crystal growth. FIG. 5 also illustrates the effect of grain 115 size on roughness. As shown, a surface formed of smaller grains has a higher density of grain boundaries, undulations, and higher Rq. Resultantly, the higher density of grain boundaries can induce additional resistivity for the wiring trace since grain boundaries are regarded as a cause of higher resistivity or lower conductivity. The gradient in grain 115 size, and hence surface roughness, may also exist along the side surfaces 112 of the wiring trace 110.

FIG. 6 is a schematic cross-sectional side view illustration of wiring traces grown with graded grain size growth in accordance with an embodiment. Similar to the illustration in FIG. 5, the first wiring traces 110A and/or second wiring traces 110B in FIG. 6 can be formed with a non-uniform, or graded (Cu) crystal growth. The graded Cu crystals can include smaller crystals, or grain sizes, underneath larger crystals. In such a configuration, the smaller grain sizes can maintain ductility for the wiring traces (e.g. for flexible applications) while the larger crystals provide a smooth top surface 111 and less grain boundaries near the top surface 111 for reduced insertion loss. Still referring to FIG. 6, in the particular embodiment illustrated the first top surfaces 111A and second top surfaces 111B may be characterized by smoother Rq than the bottom surfaces 114, while roughness of the side surfaces 112A, 112B may potentially be non-uniform, or graded.

In accordance with embodiments, the provision of smooth surfaces of the wiring traces can be balanced with the provision of rougher surfaces to provide adhesion with overlying insulation layers or to provide ductility. Referring briefly back to FIGS. 4A-4B, all wiring traces 110 can be grown with larger grain 115 sizes. The first wiring traces 110A can then be covered with a mask layer 130 while the second wiring traces 110B are subjected to a roughening operation. In the embodiment illustrated in FIG. 7, the first wiring traces 110A can be grown with different grain sizes compared to the second wiring traces 110B to provide the differential surface roughness. Notably, the larger grain 115 sizes, and hence lower Rq, can be present on all of the top surface 115, side surfaces 112A and bottom surfaces 114 of the first wiring traces 110A compared to the second wiring traces 110B. In alternative arrangements the surfaces of the wiring traces can be selectively modulated.

In the embodiment illustrated in FIG. 8, a skin layer 117 can be selectively formed on the first wiring traces 110A. As shown, both the first wiring traces 110A and second wiring traces 110B can include a bulk layer 116 characterized by the smaller grain 115 sizes, and a top skin layer 117 with larger average grain size than the bulk layer 116 that is selectively grown on the bulk layer 116 of the first wiring traces 110A. Thus, the first wiring traces 110A may be thicker than the second wiring traces 110B, and first top surfaces 111A may be smoother than the second top surfaces 111B. Side surfaces 112A may similarly have a hybrid roughness corresponding to the underlying grain 115 size.

In addition to selective growth, grain 115 size can also be locally modulated by thermal treatment, such as with laser treatment. In such a process, a laser can be used to locally heat the top surfaces 111A and/or side surfaces 112A to effect crystal growth. For example, the heat may be sufficient to locally melt the Cu surfaces and then let them solidify. Through recrystallization, the high density of local roughness due to small grain sizes and high grain boundary density can be reduced on the outermost areas of the first wiring traces 110A where high frequency signals are transmitted. Such a process is illustrated in FIGS. 9A-9B where local laser modulation is used to control surface roughness and grain size in accordance with an embodiment. As shown, both the first and second wiring traces 110A, 110B can be grown with the smaller grain sizes, with default higher roughness. Furthermore, both the first and second wiring traces 110A, 110B can optionally be subjected to an additional roughening operation, such as that illustrated in FIG. 4B. The first wiring traces 110A can then be subjected to local laser modulation to reduce roughness along the first top surfaces 111A and/or first side surfaces 112A. As a result, the first top surfaces 111A may have a larger average grain size than the second top surfaces 111B, and the first side surfaces 112A may have a larger average grain size than the second side surfaces 112B.

An artifact of laser modulation may potentially result in the underlying insulation layer 102 around the laser modulated wiring trace. As shown in FIG. 9B, the first wiring traces 110A are on a top surface of an insulation layer 102, with the top surface of the insulation layer including a bulk area 104 characterized by a bulk surface roughness (Rq) and an altered surface area 106 adjacent the first wiring traces 110A. In accordance with embodiments, the altered surface area 106 is characterized by a higher surface roughness (Rq) than the bulk surface roughness (Rq) of the bulk area 104. This may provide additional adhesion for the next insulation layer 102 to be deposited.

Up until this point various processes have been described to control surface roughness of the wiring traces, and underlying insulation layer. While illustrated separately, it is to be appreciated this is for clarity, and various processing conditions may be combined. In the following description various process flows are provided that may or may not combine multiple processes and conditions described to this point. It is to be appreciated that the following process flows are to be interpreted as particularly graceful implementations of the embodiments, and that the following process flows can be combined with other processes described herein. Furthermore, the additional process flows are not limited to the formation of a single metal routing layer, and do include the additional features of a foil layer and seed layer which can optionally be included in any of the above described embodiments.

FIGS. 10A-10H are schematic cross-sectional side view illustrations for a sequence of forming select wiring traces with smooth top surfaces in accordance with an embodiment including masking during roughening. As shown in FIG. 10A, the illustrated processing sequence resumes with the lamination an insulting layer 102 and metal (e.g. Cu) foil layer 140 over an underlying wiring trace 110. Vias 150 are then formed through the foil layer 140 and insulation layer 102 to expose the underlying wiring trace 110 as shown in FIG. 10B. For example, vias 150 may be formed by laser drilling, chemical etching, etc. A seed layer 160 can then be deposited over the underlying topography as shown in FIG. 10C. In an embodiment, the seed layer 160 is formed using electroless deposition. A patterning layer (e.g. photoresist) may then be formed (not illustrated) to form wiring trace areas. A bulk layer 116 is then formed, for example by electrolytic plating as shown in FIG. 10D. The stack-up of the foil layer 140, seed layer 160, and bulk layer 116 will become the metal routing layer 108 including the first wiring traces 110A and second wiring traces 110B.

In accordance with embodiments, the first top surfaces 111A and second top surfaces 111B of the bulk layer 116 can be tailored to have a specified surface roughness and grain size. In an embodiment, an optimized smooth electrolytic plated top surface has an RMS surface roughness (Rq) of less than 0.20 μm, or more specifically approximately 0.1 μm.

Following the formation of the bulk layer 116 a mask layer 130 can be formed on the first top surfaces 111A as shown in FIG. 10E. In an embodiment the mask layer 130 is formed by electrolytic plating of additional metal which can be selectively removed. Thus, the mask layer 130 may be formed of a metal with different composition than the bulk layer 116. For example, a nickel mask layer 130 may be plated onto a copper bulk layer 116. Flash etching may then be performed to remove the underlying seed layer 160 and foil layer 140 between the first wiring traces 110A and second wiring traces 110B as shown in FIG. 10F. For example, this may involve a wet etch process, such as a hydrogen peroxide based chemistry. In an embodiment, the flash etching process may induce an RMS surface roughness (Rq) of greater than 0.20 μm on the exposed top surfaces 111B, and exposed first side surfaces 112A and second side surfaces 112B of the wiring traces along with some amount of reduction in thickness and width. As previously indicated, presence of the foil layer 140 is optional. Where present, flash etching of the foil layer 140 may result in further roughness of the exposed wiring traces, such as greater than 0.30 μm. For example, additional minimum flash etching time related to removal of a 3 μm thick foil layer 140 may induce more roughness than minimum flash etching time related to removal of a 1 μm thick foil layer 140. In an embodiment, additional chemical or physical roughening treatments can also be performed to achieve an RMS surface roughness (Rq) of greater than 0.30 μm, or even greater than 0.40 μm.

The mask layer 130 can then be selectively removed as shown in FIG. 10G using an etchant with suitable selectivity. The processing sequence can then optionally be repeated, beginning with lamination of the next insulation layer 102 and foil layer 140 as shown in FIG. 11H. In an embodiment, the resultant first top surfaces 111A are characterized by an RMS surface roughness (Rq) that is at least 0.10 μm less than the second top surfaces 111B. The difference could be even greater such as at least 0.15 μm, or 0.20 μm, or more.

FIGS. 11A-11I are schematic cross-sectional side view illustrations for a sequence of forming select wiring traces with smooth top surfaces in accordance with an embodiment including selective growth and masking during roughening. FIGS. 11A-11I are similar to the sequence illustrated in FIGS. 10A-10H with the addition of the grown of an additional skin layer 117 to provide additional differential in roughness. Initially, the processing sequence of FIGS. 11A-11D is the same as that as previously described and illustrated with regard to FIGS. 10A-10D. As shown in FIG. 11E a skin layer 117 can be selectively formed for wiring traces 110A to provide an ultra-smooth roughness similar to the previous description with regard to FIG. 8. In an embodiment, the optimized electrolytic plating chemistry can be used to grow a skin layer 117 with larger grain size compared to the underlying bulk layer 116. In an embodiment, the top surface 111A of the skin layer 117 has an RMS surface roughness (Rq) of less than 0.10 μm, such as approximately 0.05 μm. Coincidentally, the resultant first wiring traces 110A may be thicker than the second wiring traces 110B. The following processing sequence illustrated in FIGS. 11F-11I can then be substantially the same as that previously described and illustrated with regard to FIGS. 10E-10H.

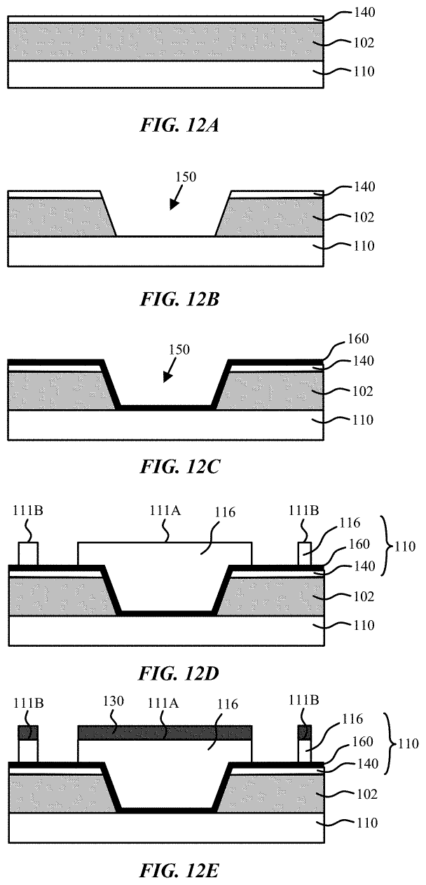

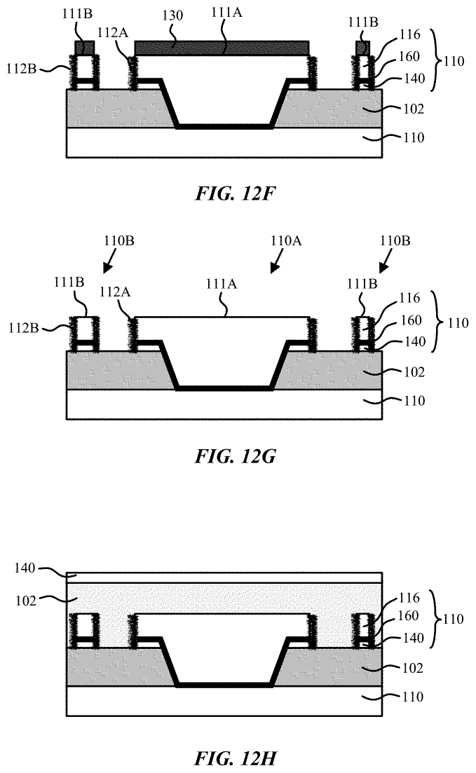

FIGS. 12A-12H are schematic cross-sectional side view illustrations for a sequence of forming wiring traces with roughened side surfaces and smooth top surfaces in accordance with an embodiment. FIGS. 12A-12H are similar to the sequence illustrated in FIGS. 10A-10H with the addition of the mask layer 130 formed over all wiring traces. Initially, the processing sequence of FIGS. 12A-12D is the same as that as previously described and illustrated with regard to FIGS. 10A-10D. As shown in FIG. 12E the mask layer 130 is formed over the bulk layers 116 for both the first wiring traces 110A and the second wiring traces 110B. The following processing sequence illustrated in FIGS. 12E-12H can then be substantially the same as that previously described and illustrated with regard to FIGS. 10E-10H. In such an embodiment, the first top surfaces 111A and the second top surfaces 111B may all be relatively smooth, with the first side surfaces 112A and the second side surfaces 112B being relatively rougher to provide adhesion with the overlying insulation layer 102.

### Example 1—Peel Strength Simulation

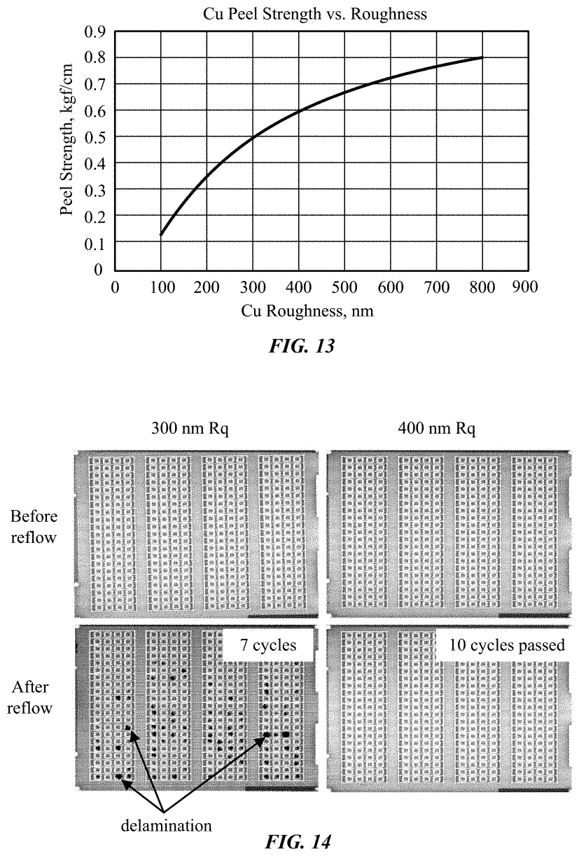

In order to illustrate the impact of wiring trace surface roughness on potential for delamination with the overlying insulation layer, simulation data is provided for peel strength as a function of top side RMS surface roughness (Rq) of copper wiring traces. Results of the simulation data is provided in FIG. 13. As shown, an inflection point appears around Rq of 300-400 nm where peel strength is significantly degraded.

### Example 2—Thermal Cycling Tests

In order to characterize practical application with simulated peel strength data, ten-metal layer routing substrates were prepared including wiring traces with top and side surfaces characterized by RMS surface roughness (Rq) values of 300 nm (subjected to 100% flash etching with hydrogen peroxide based wet etching chemistry) and 400 nm (subjected to additional 30% longer flash etching time). The routing substrates were then subjected multiple reflow cycles with peak temperature of 260° C. Test data results are provided in FIG. 14. As shown, the 300 nm Rq test samples had marginal results, with partial delamination after 7 thermal cycles. The 400 nm Rq test samples passed reflow tests after 10 thermal cycles with no delamination.

The results of the thermal cycling tests suggest embodiments including first wiring traces with smooth surfaces top and/or side surfaces can be combined with second wiring traces with rougher top and/or side surfaces of greater than 300 nm Rq, with results improving with increased Rq.

### Example 3—Insertion Loss Simulation

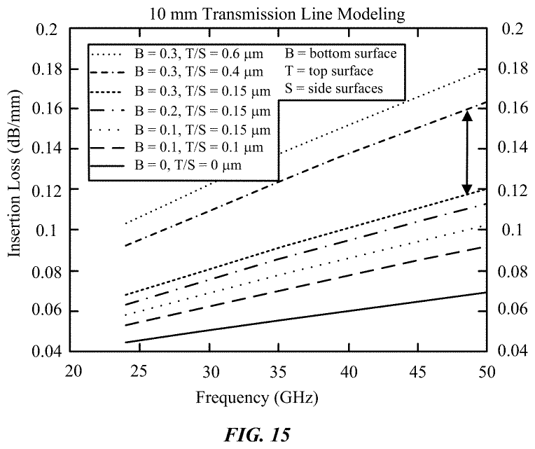

In order to illustrate the impact of wiring trace surface roughness on insertion loss at high frequencies, simulation data is prepared for an exemplary 10 mm long transmission line with various RMS surface roughness (Rq) values on the bottom surface (B), top surface (T) and side surface (S) of the wiring traces. Specifically, insertion loss data is simulated for the FR2 frequency range between 24.35 GHz to 52.6 GHz. Results of the simulation data are provided in FIG. 15. The bottom surfaces (B), top surfaces (T), and side surfaces (S) referred to in FIG. 14 correspond to the top bottom surfaces 114, top surfaces 111, and side surface 112 described elsewhere herein characterizing the wiring traces.

As already shown in Examples 1-2, RMS surface roughness (Rq) above 300 nm, and possibly 400 nm and above may be sufficient to pass thermal cycling tests. At operating frequencies of 50 GHz and above, this may correspond to insertion losses of at least 0.16 dB/mm. In such applications, use of low loss dielectric materials for insulator layers 102 can be useful, however, low loss dielectric materials have been shown to have lower adhesion than other higher loss dielectric materials. Accordingly, embodiments combine wiring traces and feature with low Rq, and may increase Rq on other wiring traces and features that do not require the low Rq in order to improve adhesion and reduce lamination, thus enabling incorporation of low loss dielectric materials as insulation layer 102. As shown, in FIG. 15, reducing wiring trace Rq additionally reduces intrinsic insertion loss of the wiring trace. At a minimum, a 25% improvement is illustrated at 50 GHz by reducing T/S Rq from 0.40 μm to 0.15 μm while maintaining bottom Rq of 0.3 μm. Additional improvements can be obtained by lowering bottom surface (B) Rq in addition to top surface (T) and side surfaces (S).

In an accordance with various embodiments, the resultant first top surfaces 111A of the first wiring traces are characterized by an RMS surface roughness (Rq) that is at least 0.10 μm less than the second top surfaces 111B. The difference could be even greater such as at least 0.15 μm, or 0.20 μm, or more. For example, the second top surfaces 111B may have an RMS surface roughness (Rq) of greater than 300 nm, such as 400 nm or more, while the first top surfaces 111A may have an Rq of 200 nm or less (e.g. optimized smooth electrolytic plated top surface described with regard to FIG. 10D) such as 150 nm, 100 nm or even 50 nm (e.g. ultra-smooth skin layer 117 described with regard to FIGS. 8, 11E). In addition, in some embodiments, volume ratios of the first wiring traces 110A and second wiring traces 110B are designed with a larger volume ratio or number of the second wiring traces 110B within a metal routing layer 108 to provide sufficient adhesion to accommodate the comparatively lower roughness first wiring traces 110A.

In utilizing the various aspects of the embodiments, it would become apparent to one skilled in the art that combinations or variations of the above embodiments are possible for forming a routing substrate with select wiring traces with lower roughness. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. A routing substrate comprising:
a plurality of metal routing layers and insulation layers;
wherein a first metal routing layer of the plurality of metal routing layers includes a first set of first wiring traces and a second set of second wiring traces; and
wherein first top surfaces of the first wiring traces are characterized by a lower root mean square (RMS) surface roughness (Rq) than second top surfaces of the second wiring traces.

2. The routing substrate of claim 1, wherein the first top surfaces of the first wiring traces have a larger average grain size than the second top surfaces of the second wiring traces.

3. The routing substrate of claim 2, wherein first side surfaces of the first wiring traces have a larger average grain size than second side surfaces of the second wiring traces.

4. The routing substrate of claim 3, wherein the first wiring traces are on a top surface of an insulation layer, the top surface of the insulation layer including a bulk area characterized by a bulk RMS surface roughness (Rq) and an altered surface area adjacent the first wiring traces, wherein the altered surface area is characterized by a higher RMS surface roughness (Rq) than the bulk RMS surface roughness (Rq).

5. The routing substrate of claim 1, wherein the first wiring traces are thicker than the second wiring traces.

6. The routing substrate of claim 5, wherein the first wiring traces include bulk layer and a top skin layer characterized by a larger average grain size than the bulk layer.

7. The routing substrate of claim 5, wherein the first top surfaces and the second top surfaces have approximately a same average grain size.

8. The routing substrate of claim 1, wherein the first top surfaces are characterized by an RMS surface roughness of less than 0.20 μm.

9. The routing substrate of claim 8, wherein the second top surfaces are characterized by an RMS surface roughness (Rq) of greater than 0.30 μm.

10. The routing substrate of claim 8, wherein the second top surfaces are characterized by an RMS surface roughness (Rq) of 0.40 μm or more.

11. The routing substrate of claim 1, wherein the first top surfaces are characterized by an RMS surface roughness (Rq) that is at least 0.10 μm less than the second top surfaces.

12. The routing substrate of claim 1, wherein the first top surfaces are characterized by an RMS surface roughness (Rq) that is at least 0.20 μm less than the second top surfaces.

13. The routing substrate of claim 1, wherein the top surfaces of the first wiring traces have a lower dislocation density than the second top surfaces of the second wiring traces.

14. The routing substrate of claim 1, further comprising a first insulation layer over the first metal routing layer, wherein the first insulation layer includes a low-loss dielectric material with a dissipation factor (Df) less than 0.007.

15. An electronic assembly comprising:
a routing substrate comprising:
a plurality of metal routing layers and insulation layers;
wherein a first metal routing layer of the plurality of metal routing layers includes a first set of first wiring traces and a second set of second wiring traces; and
wherein first top surfaces of the first wiring traces are characterized by a lower root mean square (RMS) surface roughness (Rq) than second top surfaces of the second wiring traces;
a first component coupled with the routing substrate;
a second component coupled with the routing substrate; and
wherein the first component and the second component are electrically connected with at least one first wiring trace of the first set of wiring traces.

16. The electronic assembly of claim 15, wherein the first component comprises a radio frequency integrated circuit (RFIC) die, and the second component comprises an antenna.

17. The electronic assembly of claim 15, wherein the routing substrate comprises a flexible cable.

18. The electronic assembly of claim 15, wherein the routing substrate comprises a circuit board, and the first component and the second component are mounted on the circuit board.

19. The electronic assembly of claim 15, wherein the first component comprises a central processing unit (CPU) or graphics processing unit (GPU).

20. The electronic assembly of claim of claim 15, wherein the first top surfaces are characterized by an RMS surface roughness (Rq) that is at least 0.20 μm less than the second top surfaces, and further comprising a first insulation layer over the first metal routing layer, wherein the first insulation layer includes a low-loss dielectric material with a dissipation factor (Df) less than 0.007.
